(19) United States
(12) Patent Application Publication
(10) Pub. No.: US 2018/0301578 A1
(43) Pub. Date: Oct. 18, 2018

(54) PHOTOVOLTAIC-ELECTROCHROMIC WINDOWS

(71) Applicant: View, Inc., Milpitas, CA (US)

(72) Inventor: Robert T. ROZBICKI, Germantown, TN (US)

(21) Appl. No.: 15/525,262

(22) PCT Filed: Oct. 28, 2016
(86) PCT No.: PCT/US2016/059498

§ 371 Date: May 8, 2017

Related U.S. Application Data
(60) Provisional application No. 62/247,719, filed on Oct. 28, 2015.
(60) Provisional application No. 62/313,587, filed on Mar. 25, 2016.

(51) Int. Cl. H01L 31/0475; H01L 51/00; G02F 1/163; H01L 51/44; H01L 31/09; H01L 31/048; H02S 30/10; H02S 20/22

(52) U.S. Cl. CPC H01L 31/0475; H01L 51/0032; G02F 1/163; H02S 20/22; H01L 31/09; H01L 31/048; H02S 30/10; H01L 51/441

(57) ABSTRACT

The embodiments herein relate to electrochromic windows that include a transparent photovoltaic device coating disposed thereon. In some cases, the photovoltaic device coating may be wavelength selective. In these or other cases, the photovoltaic device coating may include a perovskite-based material.

### CROSS-REFERENCES TO RELATED APPLICATIONS

This application claims benefit of U.S. Provisional Patent Application No. 62/247,719, titled “PHOTOVOLTAIC-ELECTROCHROMIC WINDOWS” filed on Oct. 28, 2015 and U.S. Provisional Patent Application No 62/313,587, titled “PHOTOVOLTAIC-ELECTROCHROMIC WINDOWS” filed on Mar. 25, 2016, both are hereby incorporated by reference in their entirety and for all purposes.

### FIELD

The invention relates generally to electrochromic devices, more particularly to photovoltaic-electrochromic windows and related controllers.

### BACKGROUND

Electrochromism is a phenomenon in which a material exhibits a reversible electrochemically-mediated change in an optical property when placed in a different electronic state, typically by being subjected to a voltage change. The optical property is typically one or more of color, transmittance, absorbance, and reflectance. One well known electrochromic material is tungsten oxide having slightly sub-stoichiometric oxygen. Tungsten oxide is a cathodic electrochromic material in which a coloration transition, transparent to blue, occurs by electrochemical reduction.

Electrochromic materials may be incorporated into, for example, windows for home, commercial and other uses. The color, transmittance, absorbance, and/or reflectance of such windows may be changed by inducing a change in the electrochromic material, that is, electrochromic windows are windows that can be darkened or lightened electronically. A small voltage applied to an electrochromic device (EC) of the window will cause them to darken; reversing the voltage polarity causes them to lighten. This capability allows control of the amount of light that passes through the windows, and presents an opportunity for electrochromic windows to be used as energy-saving devices. The energy-saving aspect of the windows can be enhanced by including certain features as described herein.

### SUMMARY

Various advanced photovoltaic-electrochromic (PV-EC) windows are presented herein. There are a number of reasons why PV films have typically not been included on electrochromic windows. However, with the advance of new PV films, particularly transparent PV films, and EC window designs, the use of PV films in combination with EC windows is a much more viable option. The PV film and EC device may each be provided on a lite, which may be incorporated into an IGU and/or laminate structure. Many different configurations are possible, with different advantages and disadvantages in each case.

In one aspect of the disclosed embodiments, a photovoltaic-electrochromic (PV-EC) window is provided, the PV-EC window including: a first substrate and a second substrate oriented substantially parallel with one another; a PV film disposed on at least one of the first and second substrates, where the PV film is transparent, and where the PV film is wavelength specific such that it selectively converts light energy at UV and/or IR wavelengths compared to visible wavelengths; and an EC device disposed on at least one of the first and second substrates.

In another aspect of the disclosed embodiments, a photovoltaic-electrochromic (PV-EC) window is provided, the PV-EC window including: a first substrate and a second substrate oriented substantially parallel with one another; a photovoltaic film disposed on at least one of the first and second substrates, where the PV film is transparent, and where the PV film includes a perovskite-based material; and an EC device disposed on at least one of the first and second substrates.

In various embodiments, the perovskite-based material may include an organotrihalometal. In some such embodiments, the organotrihalometal may be selected from the group consisting of (NH₃)MX₃, (CH₃NH₂)MX₃, (CH₃)₂N(H)MX₃, H(C═O)N(H)MX₃, HN═CN(H₂)MX₃, X—(CH₂)₃MX₃ and the like, where M is Pb or Sn, and each X is independently F, Cl, Br, or I. In certain implementations, M is Pb. In other implementations, M is Sn. In various implementations, at least one X may be F. In these or other embodiments, at least one X may be Cl. In these or other embodiments, at least one X may be Br. In these or other embodiments, at least one X may be I.

In some implementations, the organotrihalometal may have the formula (R)₃N—M(X)₃, where each R is independently selected from the group consisting of H and (C1-C6) alkyl, optionally substituted with one or more of the same or different R⁸ groups; M is lead or tin; each X is independently a halogen; R⁸ is selected from the group consisting of Rₐ, R_{b}, Rₐ substituted with one or more of the same or different Rₐ or R_{b}, —ORₐ, —SRₐ, and —N(Rₐ)₂; each Rₐ is independently selected from the group consisting of hydrogen, (C1-C6) alkyl, and (C1-C6) aryl; and either (i) each R_{b} is independently selected from the group consisting of —NRₐRₐ, halogen, —CF₃, —CN, —C(O)Rₐ, —C(O)ORₐ and —C(O)NRₐRₐ; or (ii) two of R_{b} combine to form ═O or ═N—Rₐ.

These and other features and advantages will be described in further detail below, with reference to the associated drawings.

### BRIEF DESCRIPTION OF THE DRAWINGS

The following detailed description can be more fully understood when considered in conjunction with the drawings in which:

FIG. 1A depicts construction of an Insulated Glass Unit (IGU).

FIG. 1B depicts an electrochromic device according to certain embodiments.

FIG. 2A illustrates a cross section of an electrochromic IGU having two lites.

FIG. 2B depicts a cross section of an electrochromic IGU having three lites.

FIGS. 3, 4, 5A, and 5B illustrate cross sectional views of two lite IGUs that include a photovoltaic device coating and an electrochromic device coating, each located at various positions on the IGUs.

FIG. 6 depicts an IGU having a glass sheet positioned between an electrochromic device coating and a photovoltaic device coating.

FIGS. 7-10 illustrate various three lite IGUs that include a photovoltaic device coating and an electrochromic device coating, each located at various positions on the IGUs.

FIGS. 11-13 depict laminate window structures that include both an electrochromic device coating and a photovoltaic device coating provided in different configurations.

FIGS. 14A and 14B show an IGU with a photovoltaic device coating thereon, where the IGU includes an onboard controller.

FIG. 14C depicts a conductive tape that may be used as an electrical connection in certain embodiments.

FIG. 15 illustrates the crystal structure of perovskite according to certain embodiments.

FIG. 16 depicts an example structure for a photovoltaic device coating that utilizes a perovskite-based material.

### DETAILED DESCRIPTION

Electrochromic (EC) windows may be used in a variety of settings, for example in office buildings and residential buildings. Although electrochromic windows generally use a small amount of energy, it would be beneficial to have self-powered electrochromic windows to further reduce their energy footprint and decrease installation complexity associated with hard wiring the control architecture of electrochromic windows. The use of photovoltaic (PV) films (also referred to as PV device coatings) in connection with electrochromic windows is particularly attractive because the PV films can minimize (and in some cases eliminate) the amount of grid-supplied power often used to drive optical transitions on the electrochromic windows. This may save on operating costs after the windows are installed, and also renders the windows more environmentally friendly.

For a variety of reasons, PV films have not conventionally been incorporated into electrochromic windows in practice. First, most conventional PV films are not sufficiently transparent to be aesthetically pleasing when positioned in the viewable area of a window. Such films may appear dark or opaque, or may have other aesthetic disadvantages. However, newer PV films may enable the use of such films as window coatings on electrochromic windows. These new films are significantly more transparent than previous films, providing high clarity (low haze) such that they can be added to a window without detracting from the appearance of the window. Also, improved PV films may have higher efficiency and generate sufficient power for the requirements of the EC window. The trade off with conventional transparent PV films is that in order to make the films more transparent and aesthetically pleasing, cell efficiency is sacrificed. However, new materials and improved technology provide for transparent PV films that have sufficient power and aesthetics to realize heretofore unforeseen PV-EC window technology.

Another reason that PV films or other devices have not been widely incorporated into electrochromic windows is that the conventional PV devices generate a relatively low amount of power, and such power is generated at uncontrolled times. The inclusion of a rechargeable battery can alleviate this problem, allowing solar energy to be converted, stored, and used as needed. One reason that such batteries have not been widely used is that it can be difficult to locate the battery in a place that is easily accessible (e.g., for replacing the battery as needed), aesthetically pleasing, and useful for delivering power to the bus bars of the electrochromic device. However, the use of an accessible on-board controller satisfies these conditions, and therefore renders the use of PV films more attractive. On-board controllers, as well as electrochromic devices, are further discussed in the following U.S. Patent Applications and U.S. Provisional Patent Applications, each of which is herein incorporated by reference in its entirety: U.S. Provisional Patent Application No. 62/085,179, filed Nov. 26, 2014, and titled “SELF-CONTAINED EC IGU”; and U.S. patent application Ser. No. 14/951,410, filed Nov. 24, 2015, and titled “SELF-CONTAINED EC IGU.” Electrochromic devices are also discussed in U.S. patent application Ser. No. 12/645,111, filed Dec. 22, 2009, and titled “FABRICATION OF LOW DEFECTIVITY ELECTROCHROMIC DEVICES,” which is herein incorporated by reference in its entirety.

Certain embodiments describe transparent perovskite photovoltaics. Certain of these materials contain organic groups. As used herein, the following terms are intended to have the following meanings:

“Alkyl” by itself or as part of another substituent refers to a saturated or unsaturated branched, straight-chain or cyclic monovalent hydrocarbon radical having the stated number of carbon atoms (i.e., C1-C6 means one to six carbon atoms) that is derived by the removal of one hydrogen atom from a single carbon atom of a parent alkane, alkene or alkyne. Typical alkyl groups include, but are not limited to, methyl; ethyls such as ethanyl, ethenyl, ethynyl; propyls such as propan-1-yl, propan-2-yl, cyclopropan-1-yl, prop-1-en-1-yl, prop-1-en-2-yl, prop-2-en-1-yl, cycloprop-1-en-1-yl; cycloprop-2-en-1-yl, prop-1-yn-1-yl, prop-2-yn-1-yl, etc.; butyls such as butan-1-yl, butan-2-yl, 2-methyl-propan-1-yl, 2-methyl-propan-2-yl, cyclobutan-1-yl, but-1-en-1-yl, but-1-en-2-yl, 2-methyl-prop-1-en-1-yl, but-2-en-1-yl, but-2-en-2-yl, buta-1,3-dien-1-yl, buta-1,3-dien-2-yl, cyclobut-1-en-1-yl, cyclobut-1-en-3-yl, cyclobuta-1,3-dien-1-yl, but-1-yn-1-yl, but-1-yn-3-yl, but-3-yn-1-yl, etc.; and the like.

“Aryl” by itself or as part of another substituent refers to a monovalent aromatic hydrocarbon group having the stated number of carbon atoms (i.e., C5-C15 means from 5 to 15 carbon atoms) derived by the removal of one hydrogen atom from a single carbon atom of a parent aromatic ring system. Typical aryl groups include, but are not limited to, groups derived from aceanthrylene, acenaphthylene, acephenanthrylene, anthracene, azulene, benzene, chrysene, coronene, fluoranthene, fluorene, hexacene, hexaphene, hexalene, as-indacene, s-indacene, indane, indene, naphthalene, octacene, octaphene, octalene, ovalene, penta-2,4-diene, pentacene, pentalene, pentaphene, perylene, phenalene, phenanthrene, picene, pleiadene, pyrene, pyranthrene, rubicene, triphenylene, trinaphthalene, and the like, as well as the various hydro isomers thereof. In certain embodiments, the aryl group may be a (C5-C15) aryl or, more specifically, a (C5-C10) aryl. In some cases, the aryl may be selected from the group consisting of cyclopentadienyl, phenyl, and naphthyl.

“Halogen” refers to fluoro, chloro, bromo and iodo.

### Electrochromic Devices and Windows

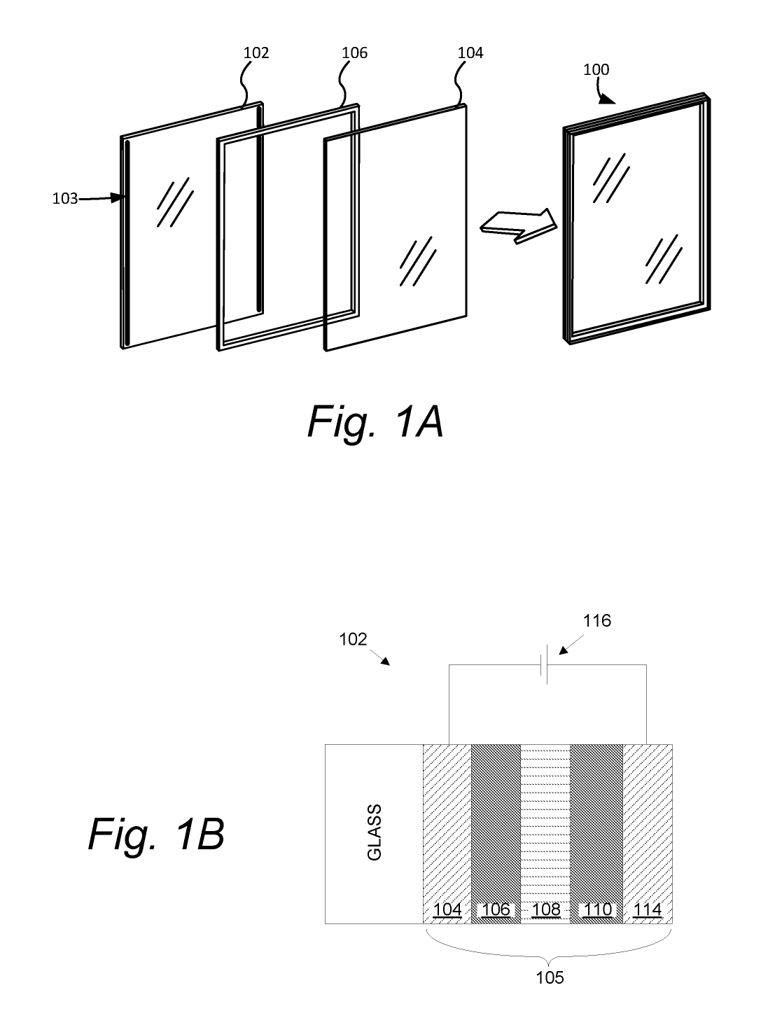

In this application, an “IGU” includes two (or more) substantially transparent substrates, for example, two panes (also referred to as lites) of glass, where at least one substrate includes an EC device disposed thereon, and the panes have a sealing separator (commonly referred to as a “spacer” in the window industry) disposed between them. One or more of the panes in an IGU may be laminated to an additional substrate. FIG. 1A, depicts an electrochromic IGU, 100, that is constructed from a first lite, 102, which has an electrochromic device coating (see FIG. 1B, e.g., electrochromic device coating 105) thereon and may include, e.g., bus bars, 103, for delivering electrical power to the electrochromic device coating. An IGU is typically hermetically sealed, e.g., using a spacer, 106, which seals between the first lite 102 and a second lite, 104. An adhesive (often referred to as a primary seal or primary sealant) may be provided between the spacer 106 and each lite 102 and 104. An additional sealing material (often referred to as a secondary seal or secondary sealant) may be provided around the outer perimeter of the spacer 106. The second lite 104 may or may not have one or more thin film coatings on it. For example, as described in certain embodiments herein, lite 104 may have a transparent PV device coating on it. The IGU 100 has an interior region, defined by the inner surfaces of lite 102, lite 104 and spacer 106, that is isolated from the ambient environment. Typically the interior region is filled with an inert gas, but in certain embodiments vacuum is provided in the interior region (thus vacuum glass units or “VGUs” are also contemplated).

A “window assembly” includes an IGU and/or laminate structure (further discussed below), and may include electrical leads for connecting the window assembly's one or more EC devices to a voltage source, switches and the like, as well as a frame that supports the IGU or laminate structure, and related wiring (if any).

As used herein, the term outboard means closer to the outside environment, while the term inboard means closer to the interior of a building, i.e., these terms describe the relative relationship of two components, e.g., film coatings or glass panes, to each other. For example, in the case of an IGU having two panes, the pane located closer to the outside environment is referred to as the outboard pane or outer pane, while the pane located closer to the inside of the building is referred to as the inboard pane or inner pane. The different surfaces of the IGU may be referred to as S1, S2, S3, and S4 (assuming a two-pane IGU). S1 refers to the exterior-facing surface of the outboard lite (i.e., the surface that can be physically touched by someone standing outside). S2 refers to the interior-facing surface of the outboard lite. S3 refers to the exterior-facing surface of the inboard lite. S4 refers to the interior-facing surface of the inboard lite (i.e., the surface that can be physically touched by someone standing inside the building). In other words, the surfaces are labeled S1-S4, starting from the outermost surface of the IGU and counting inwards. In cases where an IGU includes three panes, this same trend holds (with S6 being the surface that can be physically touched by someone standing inside the building).

A schematic cross-section of lite 102 is depicted in FIG. 1B. Lite 102 includes an electrochromic device coating, 105, on a transparent substrate, in this example glass (although plastic would suffice). The electrochromic device coating 105 includes a conductive layer (CL) 104, an electrochromic layer (EC) 106 (sometimes referred to as a cathodically coloring layer or a cathodically tinting layer), an ion conducting layer or region (IC) 108, a counter electrode layer (CE) 110 (sometimes referred to as an anodically coloring layer or anodically tinting layer or ion storage layer), and a conductive layer (CL) 114. Elements 104, 106, 108, 110, and 114 are collectively referred to as an electrochromic stack or electrochromic device coating 105. A voltage source, 116, operable to apply an electric potential across the electrochromic stack 105 effects the transition of the electrochromic device coating from, e.g., a clear state to a tinted state. In other embodiments, the order of layers is reversed with respect to the substrate. That is, the layers are in the following order: substrate, conductive layer, counter electrode layer, ion conducting layer, electrochromic layer, conductive layer.

In various embodiments, the ion conductor region 108 may form from a portion of the EC layer 106 and/or from a portion of the CE layer 110. In such embodiments, electrochromic device coating 105 may be deposited to include cathodically coloring electrochromic material (the EC layer) in direct physical contact with an anodically coloring counter electrode material (the CE layer). The ion conductor region 108 (sometimes referred to as an interfacial region, or as an ion conducting substantially electronically insulating layer or region) may then form where EC layer 106 and CE layer 110 meet, for example through heating and/or other processing steps. In some embodiments, the device contains no ion conductor region as deposited. Such devices are further described in U.S. Pat. No. 8,764,950, titled “ELECTROCHROMIC DEVICES,” which is herein incorporated by reference in its entirety.

In various embodiments, one or more of the layers shown in FIG. 1B may be deposited to include two or more sublayers. In one example, the EC layer 106 and/or the CE layer 110 may be deposited to include two or more sublayers. The sublayers within a given layer may have different compositions and/or morphologies. The sublayers may be included to promote formation of the ion conducting region 108 and/or to tune various properties of the electrochromic device coating 105. Such devices are further described in U.S. Pat. No. 8,764,950, incorporated by reference above, and in U.S. patent application Ser. No. 15/204,868, filed Jul. 7, 2016, and titled “COUNTER ELECTRODE FOR ELECTROCHROMIC DEVICES,” which is herein incorporated by reference in its entirety.

Further, an electrochromic device coating may include one or more additional layers not shown in FIG. 1B. Such layers may improve optical performance, durability, hermeticity, and the like. Examples of additional layers that may be used include, but are not limited to, anti-reflective layers, defect-mitigating insulating layers (which may be provided within or between any of the layers shown in FIG. 1B), and/or capping layers. The techniques disclosed herein are applicable to a wide variety of electrochromic device designs. Some such devices are further described in U.S. Pat. No. 9,007,674, titled “DEFECT-MITIGATION LAYERS IN ELECTROCHROMIC DEVICES,” which is herein incorporated by reference in its entirety.

In normal operation, the electrochromic device reversibly cycles between at least two optical states such as a clear state and a tinted state. In the clear state, a potential is applied to the electrochromic stack 105 such that available ions in the stack that can cause the electrochromic material 106 to be in the tinted state reside primarily in the counter electrode 110. When the potential on the electrochromic stack is reversed, the ions are transported across the ion conducting layer 108 to the electrochromic material 106 and cause the material to enter the tinted state.

It should be understood that the reference to a transition between a clear state and tinted state is non-limiting and suggests only one example, among many, of an electrochromic transition that may be implemented. Unless otherwise specified herein, whenever reference is made to a clear-tinted transition, the corresponding device or process encompasses other optical state transitions such as non-reflective-reflective, transparent-opaque, etc. Further the terms “clear” and “bleached” refer to an optically neutral state, e.g., untinted, transparent or translucent. Still further, unless specified otherwise herein, the “color” or “tint” of an electrochromic transition is not limited to any particular wavelength or range of wavelengths. As understood by those of skill in the art, the choice of appropriate electrochromic and counter electrode materials governs the relevant optical transition.

In certain embodiments, all of the materials making up electrochromic stack 105 are inorganic, solid (i.e., in the solid state), or both inorganic and solid. As opposed to organic materials that tend to degrade over time, inorganic materials offer the advantage of a reliable electrochromic stack that can function for extended periods of time. Materials in the solid state also offer the advantage of not having containment and leakage issues often associated with materials in the liquid state. Each of the layers in the electrochromic device coating is discussed in detail, below. It should be understood that any one or more of the layers in the stack may contain some amount of organic material, but in many implementations one or more of the layers contains little or no organic matter. The same can be said for liquids that may be present in one or more layers in small amounts. It should also be understood that solid state material may be deposited or otherwise formed by processes employing liquid components such as certain processes employing sol-gels or chemical vapor deposition.

In many embodiments, an electrochromic device coating may be provided on a window together with a photovoltaic device coating, as discussed herein. Although this description refers to electrochromic windows, it is not so limiting, i.e., other absorptive or reflective device coatings will also work with transparent photovoltaics.

### Conventional Photovoltaic-Electrochromic Windows

In order to drive optical transitions on electrochromic windows, a power source must be provided. In many conventional electrochromic windows, this power may be provided from the grid over a wired connection. In certain limited instances, photovoltaic devices have been incorporated into electrochromic devices.

For example, a combination of electrochromic and photovoltaic functions (from herein, “PV-EC” systems) may be employed in a system that, as a whole, is passive, i.e., when the sun is shining the power generated by the PV system is used to power the transitions of the EC system. PV-EC systems may take various approaches.

In one approach, a transparent PV coating is combined with an EC coating in a tandem fashion. This PV-EC system conventionally suffered many problems, primarily due to issues associated with the conventional PV coatings. First, conventional PV device coatings, such as silicon-based PV, are opaque. Thus when combined with an EC window, the opaque PV coating prevents an occupant from seeing through the window.

In another example, conventional “transparent” PV technology was not truly transparent; there was haze and an associated loss of light transmission when a conventional “transparent” PV coating was positioned between the sun and the EC coating (which is a typical conventional configuration). The transmissivity in the clear state of the EC coating was reduced due to the reflections from multi-layer construction and absorption of the PV coating. As an example, dye sensitized PV coatings (e.g., dye sensitized TiO₂) have associated absorption due to the dye component of the system. Another issue that can arise with this type of system when the EC coating is positioned between the sun and the PV coating is that when the EC coating tints, the PV loses power (e.g., because less light is reaching the PV coating), so it can operate only in a self-limiting fashion.

Also, conventional transparent PV technology was not robust. Typically, transparent PV coatings degrade in a relatively rapid fashion in the harsh conditions of solar radiation and heat, for example as compared to inorganic, ceramic type coatings. Moreover, although many EC systems require relatively little power, conventional transparent PV technology simply was not able to produce sufficient power for most EC device needs.

Further complicating this approach was integration of the EC and PV device coatings into an IGU. There may be compatibility issues and integration issues related to the materials of the PV and the EC coating. For example, conventional PV coatings often relied on either rigid silicon-based opaque systems or delicate organic-based materials. The inter-compatibility issues between the EC and PV technology may be overcome, but efficient integration and wiring issues were still cumbersome and/or complex. Put simply, the conventional tandem PV-EC design is too complex to construct and engineer with conventional materials and/or are aesthetically unpleasing, and therefore market adoption is prohibited.

Some approaches place conventional, more well-established, reliable and robust, opaque PV cells proximate the EC coating or situated in what would otherwise be a viewable area of the EC window. In this approach, PV cells are placed in the window frame, close to it, or share the same space as the EC device, thus blocking a portion of the viewable area. This blockage results in less solar control and poor aesthetics for the viewer. Smaller PV cells could be used to decrease the negative visual impact of the PV cells, but this approach also decreases the amount of electrical power generated, which may be insufficient to power EC device transitions. Also, the aforementioned integration issues remain, with some additional issues, including reworking or designing new framing systems, customer rejection due to poor aesthetics and the like.

### Advanced Photovoltaic-Electrochromic Windows

In various embodiments herein, advanced photovoltaic-electrochromic windows are provided. In many cases, a photovoltaic device coating may be provided on an electrochromic IGU or laminate, either on the same surface or lite as the electrochromic device coating or on a different surface or lite. The photovoltaic device coating may be a transparent PV film, and may or may not be wavelength selective. In these or other cases, the PV film may include a transparent material having a perovskite structure. In certain embodiments the transparent PV film has high clarity (low haze, e.g., less than 1% haze) and high (visible wavelengths) transmission, for example higher than 50% T, higher than 60% T, higher than 70% T, higher than 80% T, higher than 90% T or in some embodiments higher than 95% T. The photovoltaic device may replace or supplement an additional power source such as a wired connection to the grid, a rechargeable battery, etc. Replacement of the wired connection may be preferable in some cases, for example where the electrochromic windows are located in difficult-to-access locations such as a skylight or other location where it might be more difficult to route wires. Supplementing the wired connection with a PV connection may be preferable in other cases.

The window may also generate power for powering the controller/window by taking advantage of solar, thermal, and/or mechanical energy available at the window. In one example, the window may include a photovoltaic (PV) cell/panel. The PV panel may be positioned anywhere on the window as long as it is able to absorb solar energy. For instance, the PV panel, cell or film may be positioned wholly or partially in the viewable area of a window, and/or wholly or partially in/on the frame of a window. In cases where the PV film is positioned in the viewable area, the PV film may cover a portion of the viewable area or the entire viewable area. The PV panel may be part of the controller itself. Where the PV panel is not a part of the controller, wiring or another electrical connection may be provided between the PV panel and the controller.

In some embodiments, a transparent PV film is configured within an IGU or laminate, along with an EC film. The PV and EC films may be on the same substrate of the IGU or on different substrates. If on the same substrate, the EC and PV films may or may not be in direct contact with each other. In certain embodiments, wiring from the conductors of the PV and EC films pass from inside the IGU to an external surface of the IGU, e.g., traversing one or more edges of the IGU or through one or more apertures in one or more of the panes of the IGU. Generally, although the wiring for the PV and EC devices start inside the IGU and ends outside the IGU, there is no control circuitry within the IGU. In such embodiments, this greatly simplifies IGU construction and provides easy access to the controller for the end user, because the controller is outside of the IGU. In some instances the controller is modular and may be mounted on the IGU or laminate, e.g., on the inboard pane of the IGU or laminate, where the end user has ready access to the controller. The controller may have replaceable battery storage and the controller itself may be dockable to the glass surface, e.g., a cartridge-type controller with a dock/base mounted to the glass. The controller can be inserted into the dock, and thus is modular and can be replaced if needed with a new controller (e.g., a replacement controller that is the same as an earlier controller, or an upgraded controller). In this configuration, the controller is easily accessible for maintenance/upgrades. The controller may or may not lock into the dock, as desired for a particular application.

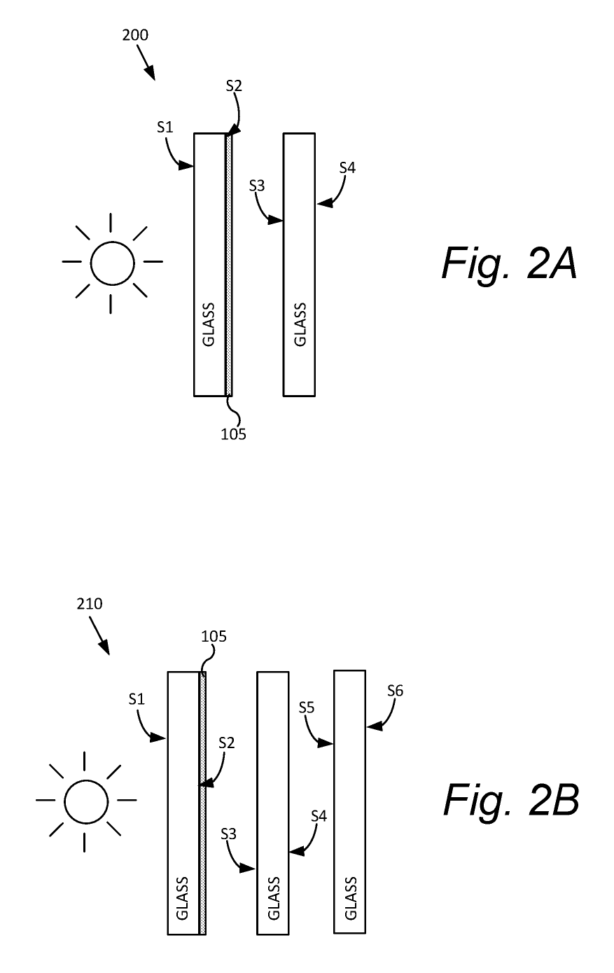

In some embodiments, the PV cell is implemented as a thin film that coats one or more surfaces of the panes. In various embodiments, the window includes two individual panes (as in an IGU for example), each having two surfaces (not counting the edges). Referring to FIG. 2A, a typical electrochromic IGU, 200, has two panes of glass (spacer not shown). Counting from the outside of the building inwards, the first surface (i.e., the outside-facing surface of the outer pane) may be referred to as surface 1 or “S1”; the next surface (i.e., the inside-facing surface of the outer pane) may be referred to as surface 2 or “S2”; the next surface (i.e., the outside-facing surface of the inner pane) may be referred to as surface 3 or “S3”, and the remaining surface (i.e., the inside-facing surface of the inner pane) may be referred to as surface 4 or “S4”. In this description, the pane exposed to the outside of the building is the “outer pane” or “outboard pane,” and the pane exposed to the interior of the building is the “inner pane” or “inboard pane.” In a triple pane IGU, the pane in between the outer and inner panes is called the “middle pane.” An electrochromic coating, 105, in the example of FIG. 2A is on S2. This configuration is typical and allows, e.g., an absorptive EC coating to keep the heat away from the interior of the building and insulated from the inner pane of glass by an inert gas fill between the inner and outer panes, typical of IGU's.

The PV thin film (or other PV cell) may be implemented on any one or more of S1-S4, singly or together with the EC film. The panes may be glass or plastic, e.g., polycarbonate or the like. When glass, the panes may be, independently, annealed glass, heat treated glass, chemically strengthened glass, or tempered glass. Glass panes may be thick or thin glass, between 0.3 mm and 25 mm thick. “Thick” glass is typically between about 3 mm and about 10 mm thick, while “thin” glass is typically between about 0.3 mm and about 2 mm thick. Thin glass is often annealed or chemically strengthened, as it is too thin to temper. Thick glass may be annealed, chemically strengthened, or tempered.

Referring to FIG. 2B, a triple pane electrochromic IGU, 210, is shown. In a triple pane IGU, surfaces 5 and 6 are referred to as “S5” and “S6,” respectively. In this example, electrochromic coating 105 is on S2, but it could also be on S3, S4 or S5 for example, to protect the coating within the hermetically sealed environment of the IGU. Photovoltaic or EC films may be coated onto exterior or interior surfaces (S1 and S4 of a double pane IGU, or S1 and S6 of a triple pane IGU) and if so, may include a protectant film (e.g., a hermetically sealed and moisture resistant film) and/or laminated with a cover pane to protect it. Standalone laminated constructs are also contemplated and are discussed in more detail below.

Typically, where a PV cell or film is contemplated for use in combination with an EC window, the EC stack is positioned toward the building interior relative to the PV film (the EC film is “inboard” of the PV film) such that the EC stack does not reduce the energy gathered by the PV cell when the EC stack is in a tinted state. As such, the PV cell may be implemented on S1, the outside-facing surface of the outer pane. However, certain sensitive PV cells cannot be exposed to external environmental conditions and therefore cannot reliably be implemented on surface 1. For example, the PV cell may be sensitive to oxygen and humidity. Other designs put the PV film inboard of the EC film and take advantage of the self-limiting properties of the system, i.e., the EC film tinting regulates how much solar energy impinges on the inboard PV film. Such designs may be desirable, e.g., so the energy absorptive properties of the EC film protect the PV film from degradation over time.

Certain transparent photovoltaics may have a color to them. In certain embodiments a colored PV device coating is used of a specific color to offset an unwanted color of the electrochromic device coating. In one example, a blue PV film is used to offset an unwanted yellow color of an EC film in an IGU and/or laminate structure. The PV film may be tuned to a specific color to offset unwanted color, transmitted and/or reflected color, of an EC device coating.

In certain embodiments, a PV film is applied to one of the window surfaces in an IGU or other multi-lite window assembly. In various cases the PV film may be transparent or substantially transparent. Examples of suitable PV films are available from Next Energy Technologies Inc. of Santa Barbara, Calif.. The films may be organic semiconducting inks, and may be printed/coated onto a surface in some cases.

Another example of suitable PV films are wavelength selective PV films made by Ubiquitous Energy, Inc. of Cambridge, Mass. and as described in U.S. 2015/0255651. Such PV films selectively absorb UV and IR wavelengths of the solar spectrum for conversion into electricity, while allowing visible bands through. In combination with EC device coatings, these transparent PV films provide excellent synergy. They not only produce power sufficient to drive the EC device (directly or indirectly via an onboard storage, e.g., a rechargeable battery), but, when outboard of the EC film, they protect the EC film from UV and IR radiation. An EC film so situated, inboard of a spectrum selective PV film, may not absorb as much energy as it otherwise would and thus may not get as hot as it otherwise would. Also, if the EC film is outboard of the PV film, then the EC film may protect the PV film from degradation over time. Certain embodiments have the alternative arrangement, where the PV film is inboard of the EC film, and thus take advantage of synergies related to that configuration.

In some embodiments, the PV film may include one or more materials having a perovskite structure. Such materials may be referred to as perovskite-based materials. The perovskite-based material may be transparent in many cases, and may exhibit a level of transmission (% T) as described above. Transparent perovskite-based materials are particularly promising for use with EC films. Suitable perovskite photovoltaic device coatings are made by Oxford Photovoltaics Limited, of Oxford, the United Kingdom.

The general chemical formula for perovskite-based materials is ABX₃, where A and B are two cations of substantially different sizes (the A cations being much larger than the B cations), and X is an anion that bonds to both. FIG. 15 shows the ideal cubic-symmetry structure, with the B cation in 6-fold coordination, surrounded by an octahedron of anions, and the A cation in 12-fold cuboctahedral coordination. However, in various perovskite-based materials, the structure may have lower-symmetry (e.g., orthorhombic, tetragonal, or trigonal), and the coordination numbers of A cations, B cations, or both, may be reduced. Certain perovskite-based materials may be in the form A(B′ₓ(B″_{y})X₃, where B′ and B″ are different elements with different oxidation states, and x+y=1. Typically, the X may be oxygen (e.g., forming an oxide perovskite), or chlorine, bromine, or iodine (e.g., forming a halide perovskite). Particular example materials are listed below.

Various ABX₃ perovskite-based materials exhibit strong light absorption, high quality charge moving characteristics (e.g., weak exciton binding energy, electron and hole diffusion lengths from about 100 nm to about 1 μm), and relatively low manufacturing costs, making these materials promising for use in connection with PV-EC windows.

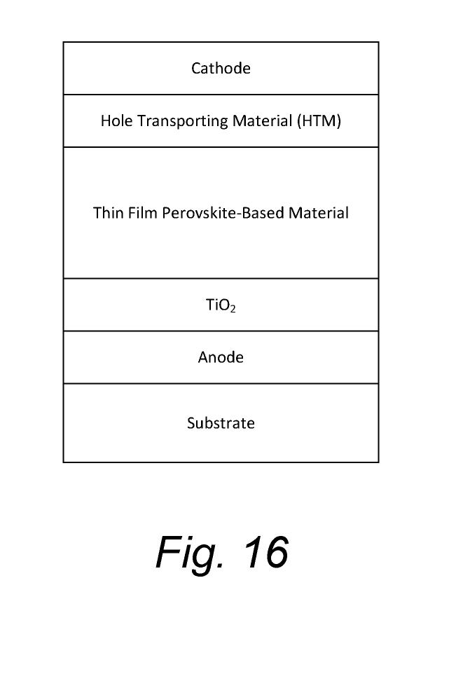

FIG. 16 depicts an example structure of a perovskite-based photovoltaic device coating. The solar cell includes a substrate (e.g., glass, plastic, etc.), an anode layer (e.g., fluorinated tin oxide (FTO), indium tin oxide (ITO), and the like), a titanium oxide layer (e.g., a compact TiO₂ layer), a thin film perovskite-based material layer (e.g., using any one or more of the perovskite-based materials described herein or a commercially available material), a hole transporting material layer, and a cathode layer (e.g., gold, silver, transparent conductive oxide (TCO), ITO, sandwiched materials like ITO-Ag-ITO (so called “IMI” conductors), etc.). Alternative materials and/or variations on the structure shown in FIG. 16 may also be used in certain embodiments.

Example perovskite-based materials that may be used in certain embodiments include, but are not limited to, organotrihalometals, e.g., of the formula (R)₃N-M(X)₃, where each R is, independently, selected from the group consisting of H and (C1-C6) alkyl, optionally substituted with one or more of the same or different R⁸ groups; M is lead or tin; each X is independently a halogen; R⁸ is selected from the group consisting of Rₐ, R_{b}, Rₐ substituted with one or more of the same or different Rₐ or R_{b}, —ORₐ, —SRₐ, and —N(Rₐ)₂; each Rₐ is independently selected from the group consisting of hydrogen, (C1-C6) alkyl, and (C1-C6) aryl; and either (i) each R_{b} is independently selected from the group consisting of —NRₐRₐ, halogen, —CF₃, —CN, —C(O)Rₐ, —C(O)ORₐ and —C(O)NRₐRₐ; or (ii) two of R_{b} combine to form ═O or ═N—Rₐ. Examples of organotrihalometals include (NH₃)MX₃, (CH₃NH₂)MX₃, (CH₃)₂N(H)MX₃, H(C═O)N(H)MX₃, HN═CN(H₂)MX₃, X—(CH₂)₃MX₃ and the like, where M is Pb or Sn and each X is independently F, Cl, Br, or I.

To address air and water sensitivity of some PV films, a film may be positioned inside the IGU, e.g., on S2 or S3 of a double pane IGU, or any one (or more) of S2-S5 in a triple pane IGU, which helps protect the film from exposure to oxygen and humidity. In some cases, the electrochromic device coating is positioned on S3 and the PV thin film is positioned on S2. In another example, the electrochromic device coating is on S2 and the PV film is positioned on S3. In yet another example, the PV film or other PV cell may be implemented on more than one surface, for example S1 and S2 (with the EC device on, for example, S2 and/or S3). In certain embodiments, there are more than one EC film, and one or more PV films. For example, each pane of a double pane IGU may have its own associated EC film, e.g., as described in U.S. Pat. No. 8,270,059, titled “Multi-pane Electrochromic Windows,” which is herein incorporated by reference in its entirety. Such windows can be modified to include at least one transparent PV film. Electrochromic device coatings as described in the aforementioned U.S. patent may be thinner than conventional EC device coatings and thus may have higher bleached state transmission. For example with reference to FIG. 1B, the electrochromic layer 106 may be between about 50 nm to about 2,000 nm thick, or about 200 nm to about 700 nm thick, or between about 300 nm to about 500 nm thick. The ion conductor layer or region 108 may be between about 5 nm to about 100 nm thick, or about 10 nm to about 60 nm thick, or about 15 nm to about 40 nm thick, or about 25 nm to about 30 nm thick. The counter electrode layer 110 may be between about 50 to about 650 nm thick, or about 100 nm to about 400 nm thick, or about 200 nm to about 300 nm thick. The conductive layers 104 and 114 may be between about 5 nm to about 10,000 nm thick, or about 10 nm to about 1,000 nm thick, or about 10 nm to about 500 nm thick, or about 100 nm to about 400 nm thick. In a particular example, the electrochromic layer 106, the ion conductor layer or region 108, and the counter electrode layer 110 have a combined thickness that is between about 100 nm to about 1200 nm.

In various embodiments, the darkest tint state of such EC films may only be about 10% T or higher. By having two EC , each film's tinting requirements may be diminished because their absorptive properties are multiplied. Two EC films having a tint state of 10% T, when combined have an effective % T of 1% T. Having diminished tinting requirements may lessen the power demand for switching the devices, and thus the power generation requirements of the PV coating may also be diminished. One embodiment is a multi-pane EC window as described in U.S. Pat. No. 8,270,059 in combination with a transparent PV device coating. For example, a double or triple-pane IGU that includes two EC device coatings, one on each of two individual lites, and at least one PV device coating. For example, a triple-pane IGU has an EC device coating on S2, a PV device coating on S3, and another EC device coating on either of S4 or S5.

In the embodiments described, solar energy may be harnessed to power the window. In some cases, PV cells are used in combination with one or more other energy storage devices such as batteries, fuel cells, capacitors (including super-capacitors), etc. These may be configured to store energy generated by the PV cell while the electrochromic device is in a clear, or relatively clear, state. A window controller may dictate this behavior. In certain embodiments, the controller also directs the energy storage cell to discharge, e.g., to drive a window bleaching transition when the electrochromic device coating is tinted, or vice versa. This behavior is particularly appropriate when the PV cell resides at a location interior to the electrochromic device, i.e., inboard of the EC device. In such embodiments, a controller may have an override function, to clear the EC device in the event the battery is running low, e.g., even if the current user command dictates tinting the EC film, the controller may override this function to recharge or preserve battery power. Generally speaking, the window controller controls both the EC film and the PV film's delivery of power to the EC film and/or the battery. If the PV film is inboard of the EC film, then the EC film's tint state may limit the ability of the PV film to generate power, but with onboard storage, this issue can be managed.

In certain embodiments, the PV film generates sufficient capacity to power the EC film and additional excess power. This additional power may be used to power the EC controller, that is, in certain embodiments the EC/PV window is totally self-contained; no externally-sourced wires need to be connected to the window for power or control communication. Wireless communication is used and the PV film, alone or with an onboard battery or other storage device (e.g., in the controller or separate from the controller) supplies sufficient power to operate the EC window's functions.

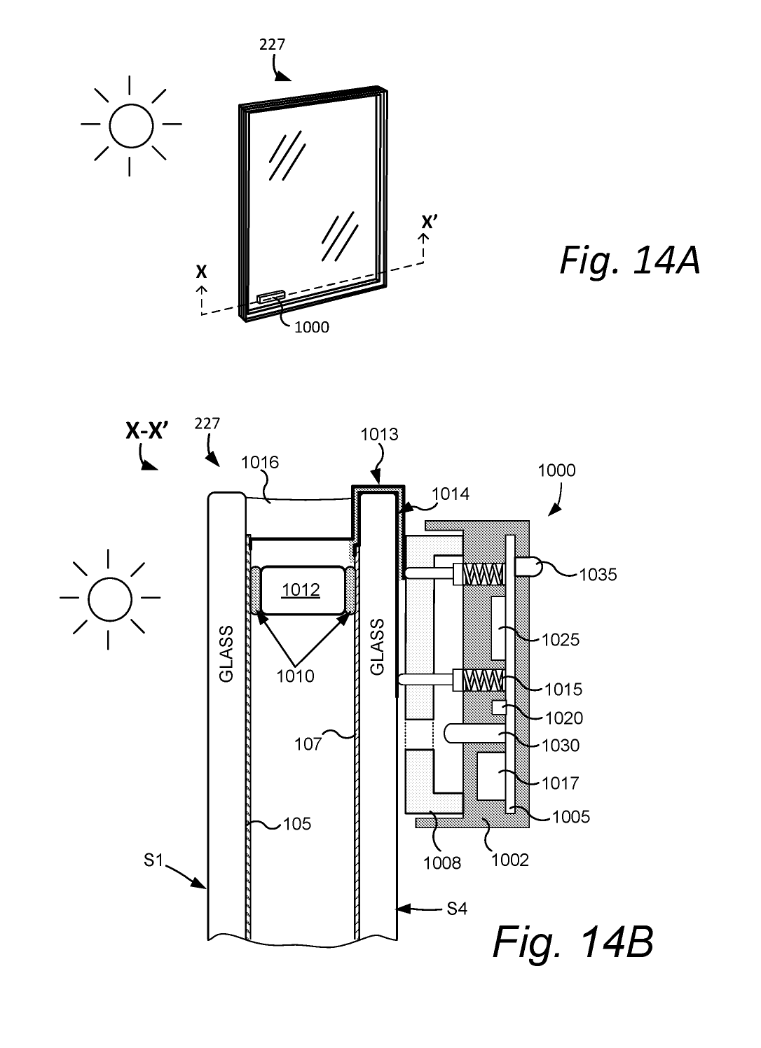

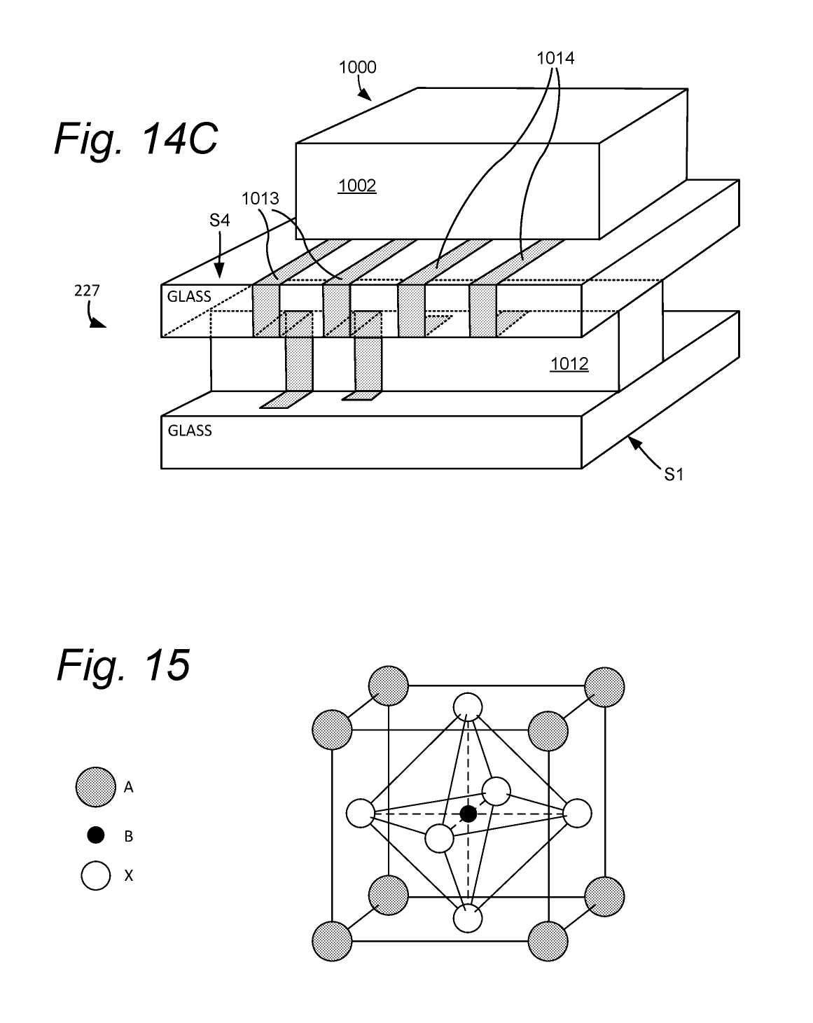

For simplicity, the following description focuses on the configurations of the PV and EC films relative to the panes of IGUs and not the accompanying wiring, batteries, controllers, spacers, seals or other components. It is understood that controllers may include onboard controllers as described in U.S. Provisional Patent Application No. 62/085,179, and U.S. patent application Ser. No. 14/951,140, each incorporated by reference above. Examples depicting onboard controllers are shown in FIGS. 14A-14C, described further below. Also, for simplicity, the following figures only include one PV film and one EC film per construct; however, any of the configurations may include two or more of each of the PV and/or EC films.

Referring to FIG. 3, a PV-EC IGU, 215, is shown. In this embodiment, a PV film, 107, e.g., as described above, is on S1, and an EC film, 105, is on S2 of the IGU. Thus, PV film 107 is outboard of EC film 105. The PV film 107 may have a protective and/or strengthening coating (not shown) to prevent moisture, UV, impact, or other external forces from degrading it. The protective coating may be organic or inorganic, e.g., a spray-on coating or a cover glass laminated to the PV film 107. If the PV film 107 is UV sensitive, then a UV absorbing function may be incorporated into the protective coating. In the case where the PV film 107 converts UV radiation to electricity, then a UV absorbing function need not be in the protective film. The protective film could be a thin glass, like Gorilla® or Willow® glass (of Corning, Inc. of Corning, N.Y.), which is laminated to the PV film 107. In one embodiment the PV film 107 also serves as the adhesive that holds the thin glass to the outer pane. Adding a strengthening pane to a pre-fabricated EC IGU is described in U.S. Pat. No. 8,164,818, which is incorporated by reference herein in its entirety. One benefit of construct 215, is that it may be fabricated, e.g., by starting with a pre-existing EC IGU and applying PV coating 107 and any protective coating, as described. For example, the PV device coating is applied to thin annealed glass, such as Corning glass, then the PV device-coated glass is processed, cut to size, and applied to an existing EC IGU. This allows for no disruption of current EC IGU process flow, but rather existing EC IGU's may be converted to PV-EC IGU's by additive processes. Thus existing inventory of EC IGU's can be diverted for PV-EC use and flexibility in assembly lines is possible, e.g., the end of the EC IGU line can have a fork, where IGU' s go directly to inventory and/or packaging for shipment or flow to the PV coating line for further processing. In this embodiment, certain electrical connections for the PV coating to the controller may be, e.g., pre-applied to S4 of the IGU, e.g., proximate the connections for the EC device to the controller. This may save time and money, if and when pre-existing IGU's are to be converted to PV-EC IGUs.

In one example, the PV film on S1 (or other surfaces in embodiments described herein) is provided on a flexible transparent substrate with the PV film pre-applied thereon, where the flexible transparent substrate is attached to S1 (or other surfaces). Such flexible substrates may also include an adhesive coating, for “peel and stick” application. In other embodiments, conventional lamination techniques may be used to adhere a flexible substrate with the PV film to a surface, e.g., an IGU lamination press/process may be used to apply the flexible PV construct to the IGU or a pane of an IGU prior to fabrication of the IGU. In certain embodiments the EC film is also supported by a flexible transparent substrate and applied adhesively to a pane of an IGU and/or a flexible transparent substrate with the PV film pre-applied thereto. Various embodiments described herein exemplify such methods. One advantage of using thin flexible substrates is that roll to roll processing may be used, which allows for high throughput and efficient fabrication.

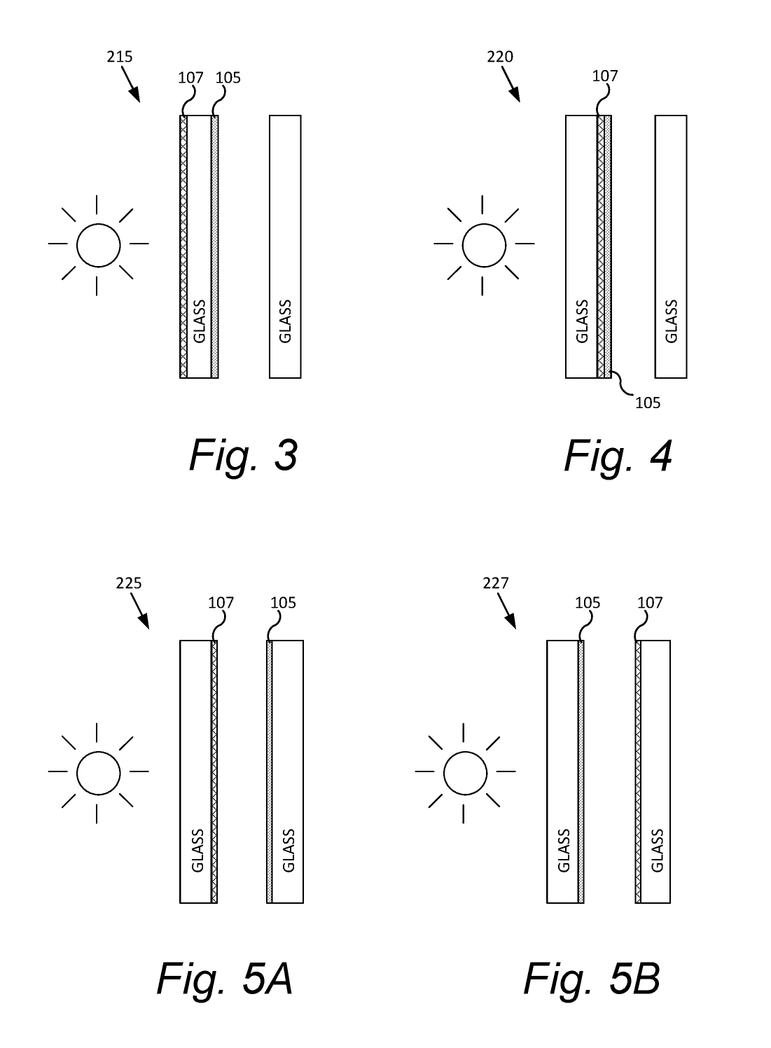

Referring to FIG. 4, a PV-EC IGU, 220, is depicted. In this example, PV film 107 is on S2 along with EC film 105. In this example, the coatings may be applied one atop the other, depending on the materials used and their respective compatibility to the process conditions required to fabricate them in this way. In this example, PV film 107 is outboard of EC film 105. In another embodiment, not shown, the two films positions are switched, i.e., they are both on S2 but the EC film is outboard of the PV film. In one such example, the EC film is an all solid state and inorganic EC film and the PV film is applied to the EC film after the EC film is formed on the substrate. In this way, the PV film is not subjected to the harsh processing conditions often associated with forming an all inorganic EC film, e.g., heating to upwards of 300-400° C. Since the PV film is inboard of the EC film, when the EC film is tinted it will block some or all of the energy used by the PV film to generate electricity. This is acceptable because, e.g., with onboard storage such as a rechargeable battery, the PV film can generate power while the EC film is in lighter tint states or clear, and that power can be saved for use, e.g., when the PV film cannot generate sufficient power to transition the EC device due to the EC device being tinted. An adhesive layer may be applied between the films and/or between either of the films and S2 of the glass depending upon which film is proximate the glass surface.

Referring to FIG. 5A, a PV-EC IGU, 225, is shown. In this embodiment, PV film 107 is on S2 and EC film 105 is on S3, i.e., the PV film is outboard of the EC film. This configuration has the advantage that each film may be processed separately on different substrates and the two substrates joined later to form the IGU. Thus, if the two films have very different processing conditions, this is easily accommodated. Having the films inside the hermetically sealed interior of the IGU protects them from the environment and obviates the need for any protective films, though such films might be used and can take the form of, e.g., an antireflective layer on one or both of the PV and EC films.

Referring to FIG. 5B, a PV-EC IGU, 227, is shown. In this embodiment, PV film 107 is on S3 and EC film 105 is on S2, i.e., the PV film is inboard of the EC film. This configuration also has the advantage that each film may be processed separately on different substrates and the two substrates joined later to form the IGU. Thus, if the two films have very different processing conditions, this is easily accommodated. Having the films inside the hermetically sealed interior of the IGU protects them from the environment and obviates the need for any protective films, though such films might be used and can take the form of, e.g., an antireflective layer on one or both of the PV and EC films. As described above, since the PV film is inboard of the EC film, when the EC film is tinted it will block some or all of the energy used by the PV film to generate electricity. This is acceptable because, e.g., with onboard storage such as a rechargeable battery, the PV film can generate power while the EC film is in lighter tint states or clear, and that power can be saved for use, e.g., when the PV film cannot generate sufficient power to transition the EC device due to the EC device being tinted. In one such example, the EC film is an all solid state and inorganic EC film and the PV film is an organic based film, e.g., transparent, in another example the PV film is spectrum selective and transparent. Since the films are on separates panes, the PV film is not subjected to the harsh processing conditions often associated with forming an all inorganic EC film, e.g., heating to upwards of 300-400° C. Another advantage of the configuration of IGU 227 is that the EC film 105 is on S2, and thus when it absorbs the sun's energy and the outer pane gets hot, this heat is kept away from the interior of the building by virtue of the intervening inert gas fill (or vacuum) of the interior volume of the IGU.

Referring to FIG. 6, a PV-EC IGU, 230, is shown. In this embodiment, PV film 107 is on S2 and EC film 105 is also on S2, inboard of PV film 107. In this configuration, there is thin glass film, 109, such as the thin glass described above, in between PV film 107 and EC film 105. There may be a lamination adhesive (not shown) between PV film 107 and thin glass 109. For example, PV film 107 may be fabricated on S2 of the outer pane. Separately, EC film 105 is fabricated on thin glass 109. Then EC film 105 on thin glass 109 is mounted to PV film 107 with an adhesive therebetween (for example the EC film 105 plus thin glass 109 is a “peel and stick” construct or adhesive is applied to either PV film and/or thin glass 109 and they are laminated together). This configuration and fabrication process have the advantages of e.g., IGU 225 or 227, where the films are processed on separate panes, but also has an additional advantage that both PV film 107 and EC film 105 reside on S2 of the final construct. In this embodiment there are several advantages, including: 1) the PV film is outboard of the EC film (see above advantages), 2) each film is processed on a separate substrate, 3) both films are protected in the hermetically sealed interior of the IGU, 4) the heat absorbed by the EC coating is insulated from the building's interior by the inert gas fill (or vacuum) of the IGU interior volume, 5) electrical connection between the films or to the common battery and/or controller circuit does not have to run from S3 of the inner pane to S2 of the outer pane, 6) choice of inner pane can be made regardless of the properties or constraints associated with the outer pane, 7) any adhesive used to laminate thin glass 109 to PV film 107 can be tailored to accentuate the optical properties of the final construct, e.g., color, or used as an additional UV filter to protect EC film 105, and 8) as in previous embodiments described, PV film 107 may also serve the function of a lamination adhesive.

Referring again to FIG. 6, in an alternative embodiment (not depicted), the position of the EC film 105 and thin glass 109 may be reversed. That is, EC film 105 may face PV film 107 (as in FIG. 4, see also FIG. 11), and a lamination adhesive (or PV film 107 acting as an adhesive) may be sandwiched between PV film 107 and EC film 105. In this example, thin glass 109 faces the interior volume of the IGU. In an alternative embodiment (not depicted) similar to IGU 230, the position of the EC film 105 and PV film 107 may be reversed. That is, both the PV film 107 and EC film 105 are on S2, with EC film 105 outboard of PV film 107. In this example, EC film 105 is touching S2 and thin glass 109, which includes PV film 107. In another similar embodiment, EC film 105 is provided on surface S2, and is also in contact with PV film 107, with thin glass 109 facing the interior volume of the IGU, with adhesive provided as desired for a particular application.

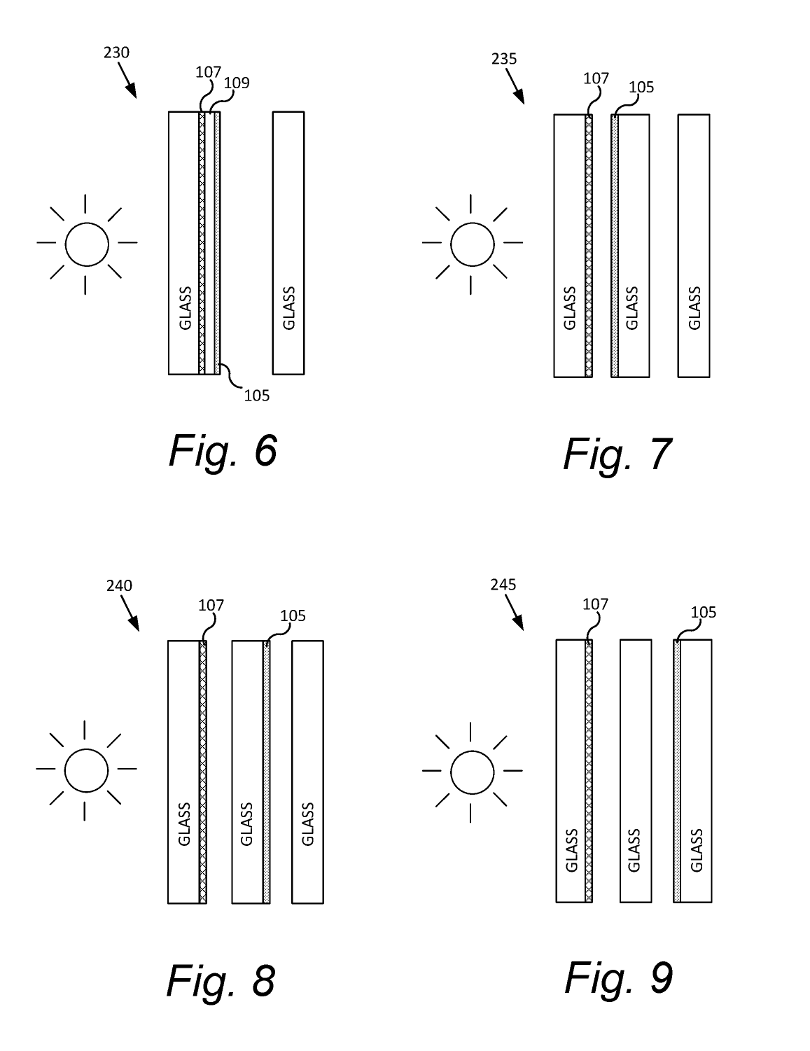

FIG. 7 depicts a PV-EC IGU, 235, which is a triple pane construct. Insulated glass unit 235 is much like IGU 225 described in relation to FIG. 5A, but IGU 235 has an extra pane. In this example the outer pane bears PV film 107 on S2, the middle pane bears EC film 105 on S3, and there is an inner pane. One advantage of this embodiment, e.g., over IGU 225 of FIG. 5A, is that the interior of the building is no longer exposed to the heat load on the pane having EC film 105, because there is an additional pane, the inner pane, and the inert gas (or vacuum) volume between the inner pane the middle pane. This embodiment also shares the advantage that the PV film 107 and EC film 105 can be fabricated and processed on separate panes and then made into the IGU. In an alternative embodiment, PV film 107 is on S3 and EC film 105 is on S2.

FIG. 8 depicts a PV-EC IGU, 240, which is a triple pane construct. Insulated glass unit 240 is much like IGU 235 described in relation to FIG. 7, but IGU 240 has EC film 105 on S4. This embodiment has the advantages of IGU 235 with an additional advantage, e.g., that it can be constructed from a pre-existing EC IGU, by adding the outer pane bearing PV film 107. In an alternative embodiment, PV film 107 is on S4 and EC film 105 is on S2. This embodiment can also be fabricated from a pre-existing EC IGU, by adding PV film 107 to S4 of an EC IGU, and then providing the inner pane to form the three pane IGU construct.

FIG. 9 depicts a PV-EC IGU, 245, which is a triple pane construct. Insulated glass unit 245 has PV film 107 on S2 and EC film 105 on S5. This embodiment shares the advantage of separate processing of the PV film 107 and EC film 105, and can also be constructed from a pre-existing EC IGU, by adding the outer pane bearing PV film 107. In an alternative embodiment, PV film 107 is on S5 and EC film 105 is on S2. This embodiment can also be fabricated from a pre-existing EC IGU, by adding the inner pane bearing PV film 107.

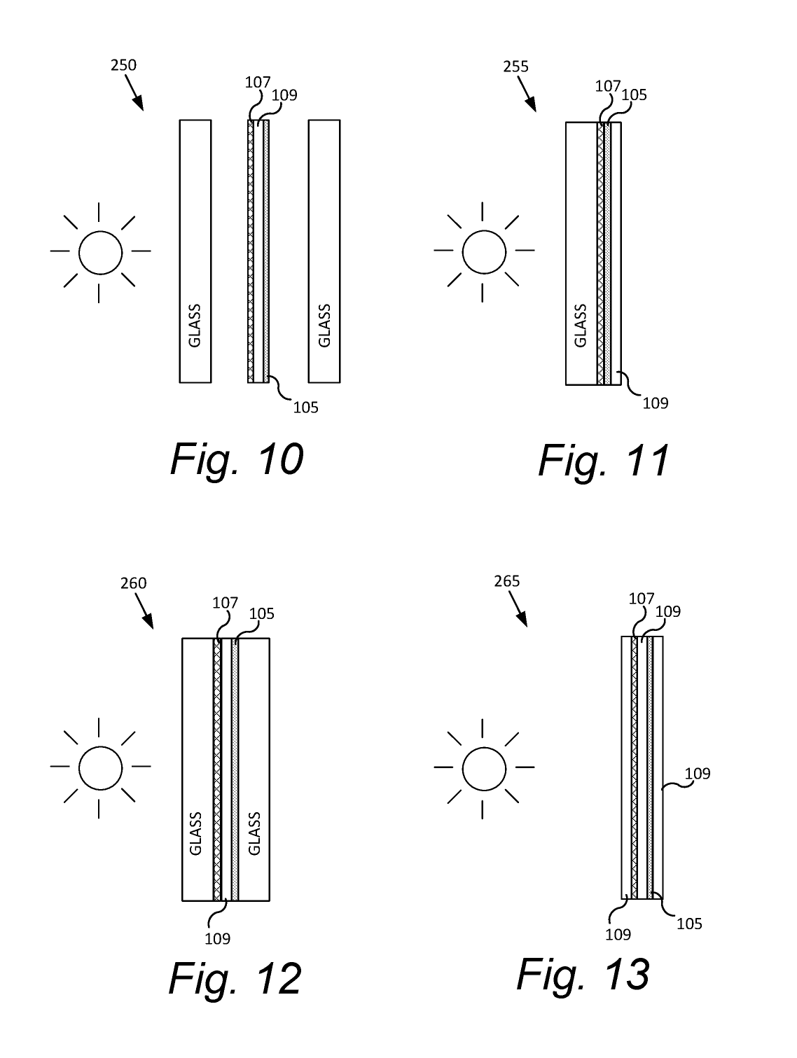

FIG. 10 depicts a PV-EC IGU, 250, which is a triple pane IGU. In this embodiment, neither the outer pane nor the inner pane have a PV or an EC film, but rather the middle pane bears both films. The outer and inner panes may include other coatings, such as AR coatings, self-clean coatings (such as TiO₂) and the like as known in the window industry. In this embodiment, the middle pane has both PV film 107 and EC film 105. In the particular embodiment depicted, the middle pane is thin glass 109, but this is not necessary, it may be thicker glass, alternatively. In the embodiment shown, each of the PV and EC films are on opposite sides of the middle pane; PV film 107 is on S3 and EC film 105 is on S4. In the particular embodiment depicted, PV film 107 in outboard of EC film 105, but this arrangement may be reversed. Also, the EC and PV films may be on the same side of the middle pane, with the PV film 107 being either inboard or outboard of the EC film 105. The embodiment shown in FIG. 10 has the advantage that both the PV film 107 and the EC film 105 are protected by separate hermetically sealed inert gas volumes (like some of the other embodiments described above). Also, the choice of outer pane and inner pane can be made regardless of the properties or constraints of the middle pane. Also, in the embodiment shown, the PV film 107 and the EC film 105 are fabricated on opposite sides of the same pane. Thus, e.g., an inorganic all solid state EC film 105 may be first fabricated on the middle pane, followed by fabrication of the PV film 107 on the other side. Thus, the PV film 107 may avoid the aforementioned harsh conditions typically used to fabricate EC films. Another advantage, in particular when thin glass 109 is used, is that the middle pane may be suspended between the outer and inner panes, e.g., by clamping two spacers on either side of the middle pane or using a spacer that has an analogous clamping function. In one embodiment, the middle pane is suspended within what is essentially a conventional double pane IGU, thus decoupling the stresses experienced by the IGU from the suspended middle pane therebetween. For example, the middle pane may be adhesively applied to a plastic membrane that is clamped between two spacers as a middle pane of a triple pane IGU would be, where the middle pane is smaller in area than the inner perimeter of the spacers. Thus the middle pane is e.g., centered on the plastic membrane and substantially insulated from stresses experienced by the IGU around it and protecting it. In an alternative embodiment, PV film 107 is on S4 and EC film 105 is on S3. This construct has the advantage that both the PV and EC film are protected from the environment, and they each have their own protective inert gas volume.

FIG. 11 depicts a PV-EC laminate, 255. In this embodiment, PV film 107 is outboard of EC film 105, and the two films are either adjacent (where PV film 107 serves also as a lamination adhesive) or there is a lamination adhesive (not shown) in between them. Thin glass 109 is inboard of the PV film 107 and EC film 105. The inboard pane need not be thin glass, it can be thick glass. Analogously, the outboard pane need not be thick glass, it can be thin glass. In the particular embodiment shown, the inboard pane is thin glass and the outboard pane is thick glass. Again, as described in certain embodiments above, PV film 107 and EC film 105 can be fabricated on separate panes and then laminated together to form laminate 255. In an alternative embodiment, the order of the films may be switched, inboard to outboard and vice versa, respectively. In one embodiment, laminate 255 serves as the outboard pane, or the inboard pane, of a double or a triple pane IGU. In another embodiment, laminate 255 serves as the middle pane of a triple pane IGU.

FIG. 12 depicts a PV-EC laminate, 260. In this embodiment, PV film 107 is outboard of EC film 105, and the two films are separated by a middle pane, in this example thin glass 109. The inboard and outboard panes need not be thick glass, they can be, independently, thin or thick glass (FIG. 13 shows an embodiment, 265, where all three panes are thin glass 109). In the particular embodiment of FIG. 12, the inboard pane is thick glass and the outboard pane is also thick glass. Again, as described in certain embodiments above, PV film 107 and EC film 105 can be fabricated on separate panes and then laminated together to form laminate 260. In an alternative embodiment, the order of the films may be switched, inboard to outboard and vice versa, respectively. In one embodiment, laminate 260 serves as the outboard pane, or the inboard pane, of a double or a triple pane IGU. In another embodiment, laminate 260 serves as the middle pane of a triple pane IGU. In one embodiment, laminate 265 serves as the outboard pane, or the inboard pane, of a double or a triple pane IGU. In another embodiment, laminate 265 serves as the middle pane of a triple pane IGU.

As mentioned, one or more electrical connections may be provided to allow the energy generated by the PV film to be routed and stored, as desired. In some cases the PV-generated energy may be routed directly to bus bars of an electrochromic device. In various other cases, the PV-generated energy may be routed to a rechargeable battery or other form of energy storage, e.g., as described above. The battery may be positioned at any location on or in an IGU. In a number of cases, the battery may be positioned in a window controller. The window controller may be mounted on or near the associated IGU, for example on S4 of a double pane IGU or surface 6 of a triple pane IGU.

FIGS. 14A and 14B depict embodiments of an IGU, 227, having an on-glass controller, 1000. IGU 227 is also shown in simplified cross section in FIG. 5B. Cross-section X-X′ shows some detail of the on-glass controller. Controller 1000 has a body, 1002, (sometimes referred to as a carrier) which in this example contains a circuit board, 1005. Controller 1000 may be mounted to e.g., S4 of IGU 227 via base, 1008, (sometimes referred to as a dock) which is, e.g., attached to surface S4 of an inboard lite via pressure sensitive adhesive (not shown) or a different adhesive or other attachment means. Body 1002 docks with base 1008 in a reversible/removable fashion as described herein. The electrochromic device coating 105 may, e.g., traverse the primary sealant, 1010, of the IGU, and between spacer 1012 and the glass. Electrical connection is established between EC device coating 105 and the circuit board 1005, and between PV device coating 107 and the circuit board 1005, via electrical connections 1013 and 1014, respectively, and a connector, in this example such as one more pogo pin type connectors, 1015. Energy generated by PV film 107 may be routed to eventually reach an energy storage device 1017 provided in controller 1000. Electrical connections 1013 and 1014 may traverse the secondary sealant 1016 and/or primary sealant 1010 (though in this example they only traverse the secondary sealant 1016). In this example, electrical connections 1013 and 1014 are routed around the edge of the inboard lite and have an insulating material between them, though a number of different electrical connections are available, such as running the electrical connections through one or more apertures through the inboard lite. While FIGS. 14A and 14B each show the PV film on S3 and the controller on S4, this is not always the case, as described herein. The types of electrical connections shown in FIGS. 14A-14C may be modified to route power from a PV film located on any surface of the IGU to a battery, supercapacitor or other energy storage component located anywhere on or near the IGU. In some alternative embodiments, both the PV film 107 and the EC film 105 are on S2 (or both on S3), in some other embodiments the PV film 107 is on S2 and the EC film 105 is on S3. Other embodiments, for example those described in relation to FIGS. 3-13, can also take advantage of the electrical connectivity described herein without undue experimentation.

Printed circuit board (PCB) 1005 may include a variety of components installed thereon including EC device and PV device control circuits, power storage and the like. Only a few examples are depicted in this figure to exemplify the basic architecture of the controller. In this example, component 1017 is an energy storage device such as a rechargeable battery. The various components on the circuit board may all be provided on a single side of the circuit board in some cases, while in other cases components may be provided on both side of the circuit board. Optionally, an interior light sensor 1035 may protrude from (or measure through) an aperture in the body 1002 of controller 1000, thereby enabling the interior light sensor 1035 to measure the level of light in a room in which IGU 227 is installed. Similarly, an optional exterior light sensor 1030 may be provided to measure the level of light from the external environment, e.g., to measure how much light is passing through IGU 227. Exterior light sensor 1030 may be positioned interior of the perimeter defined by spacer 1012, within the viewable area of the IGU 227 in some cases. An aperture in base 1008 may be provided to ensure that the exterior light sensor 1030 can measure exterior light levels when the exterior light sensor is mounted in the controller 1000 and facing outward as depicted.

Electrical connections 1013 and 1014 are not drawn to scale, they may be (singly or collectively) provided as a thin tape patterned with conductive lines (e.g., copper ink, silver ink, etc.), a ribbon cable, another type of cable, a clip patterned with conductive lines thereon or therein, wires, a different type of electrical connection, or some combination thereof. FIG. 14C depicts controller body 1002 docked on S4 of IGU 227 and electrical connections 1013 and 1014. In this example, two each of these connections are shown, but there could be more such connections. In this example electrical connections 1013 emanate from under controller body 1002 on S4 (e.g., from under base 1008 as shown in FIG. 14B), go around the edge of the glass to S3, pass beside or along spacer 1012, and end on S2 where they meet with, for example, a bus bar tab (not shown) for each bus bar of EC device coating 105 (not shown in FIG. 14C). Electrical connections 1014 emanate from under controller body 1002 on S4 (e.g., from under base 1008 as shown in FIG. 14C), go around the edge of the glass to S3 where they meet with, for example, a bus bar tab or other electrical lead (not shown) for PV device coating 107 (not shown in FIG. 14C). The electrical connections 1013 and 1014 may have protective insulator coatings. The glass may be notched on the edge to accommodate the leads and protect them from abrasion during handling and/or installation of IGU 227. In other embodiments, the electrical connections between controller 1000 (e.g., base 1008 and/or body 1002) and the EC device coating 105 and the PV device coating 107 run through the glass, e.g., holes are drilled in the glass prior to tempering (if tempered) and wires, pins, or other electrical connections are passed through the holes. In such examples the electrical connections may not be visible to the end user as they are concealed by controller 1000. The holes may or may not be in the viewable area, and in some cases the holes in the glass are positioned in the secondary seal area of the glass.

Although not shown in FIGS. 14A-14C, an electrochromic film may be provided on any one or more of S1-S4. The types of electrical connections shown for delivering power between a PV film and a controller may also be used to deliver power between a controller and the bus bars of the electrochromic device. In such cases, an additional electrical connection such as electrical connections 1013 and/or 1014 may be provided to deliver power from the controller to bus bars. As shown in FIG. 14B, a voltage controller 1020 may be provided somewhere in or on the IGU, in some cases in the controller 1000 (e.g., in controller body 1002 or base 1008). The voltage controller may act to provide an appropriate voltage for charging an energy storage device (e.g., battery, trickle charge battery, supercapacitor, etc.). Similarly, the controller (or other component) may include an appropriate circuit (not shown) for recharging the energy storage device via energy delivered from the PV film.

In certain cases, the energy storage device 1017 can aid operation of the electrochromic device, for example when a logic device, 1025, (e.g., a controller implemented on an embedded micro controller, programmable logic controller, or application specific integrated circuit) includes instructions to turn off external power to the EC system or during the colored holding period when minimal power is required to offset leakage current through the EC device, or to store energy for later use. In some implementations, the controller may include systems on a chip (SOCs), for example from the Kirkwood series of processors from Marvell Semiconductor, Inc. of Santa Clara, Calif., or from the PIC series from Microchip Technology of Chandler, Ariz. In one embodiment, controller 1000 receives input via an infrared (IR) signal, e.g., from a touch pad from the interior of the room where the IR signal passes through an IR transparent window, e.g., in the frame. A remote controller may also provide instructions to controller 1000.

In various embodiments, controller 1000 includes an antenna that is e.g., patterned onto surface S1, S2, S3 and/or S4, as described below. For instance, IGU 227 and/or controller 1000 may include a ground connection (or ground plane) for the antenna. Although only two pogo pins 1015 are shown in FIG. 14B, any number of pogo pins 1015 may be provided, as needed to receive power from the PV film 107 and power different components, including the bus bars, antennae, etc.

In each of FIGS. 14A-14C, a particular number of electrical connections are shown providing power between S4 and S2. However, it should be understood that such connections can also be used to deliver power from a controller to the bus bars, and that each electrochromic window has two (or more) bus bars. Therefore, a number of electrical connections/pogo pins/etc. may be provided to route power as needed for the different components.

Alternatively, or in addition to the PV cell, a window may include one or more other energy/power sources such as thermoelectric generators, pyroelectric generators, piezoelectric generators, acoustic generators, batteries, wired connection to the grid, etc.

Any of the embodiments shown or described herein may be configured in a particular way with regard to the bus bars and the edges of the electrochromic and photovoltaic devices. In many cases, the bus bars for the electrochromic device(s) and/or for the photovoltaic device(s) may be provided outside of the viewable area of the window. Similarly, the edges of the electrochromic device(s) and/or the edges of the photovoltaic device(s) may be provided outside of the viewable area of the window, thereby ensuring that (a) the entire viewable area tints with coloration of the device, and/or (b) the entire viewable area functions as a photovoltaic device. This configuration provides an aesthetically pleasing window at least because the bus bars are not obscuring the view through the window, and because the entire viewable area tints. In one example, the bus bars of the electrochromic device(s) and/or photovoltaic device(s), as well as the edges of the electrochromic device(s) and photovoltaic device(s) may be provided and sealed in a primary seal of an IGU, between a lite and a spacer. Any of the embodiments described herein, including but not limited to those shown in FIGS. 1A, 2A, 2B, 3, 4, 5A, 5B, 6-13, and 14A-14C, may have bus bar and device edge configurations as described in this section. In embodiments where no spacer is provided (e.g., some embodiments of FIGS. 11-13), the bus bars, as well as the edges of the electrochromic and/or photovoltaic device(s), may be provided proximate the edges of the lites, e.g., in an area that will be obscured by a frame or by another component when the window is manufactured or installed. Configurations having the described bus bar and electrochromic device edge configurations are further described in U.S. Pat. No. 8,164,818, and in U.S. patent application Ser. No. 13/456,056, filed Apr. 25, 2012, each of which is herein incorporated by reference in its entirety.

Although the foregoing invention has been described in some detail to facilitate understanding, the described embodiments are to be considered illustrative and not limiting. It will be apparent to one of ordinary skill in the art that certain changes and modifications can be practiced within the scope of the appended claims.

1. A photovoltaic-electrochromic (PV-EC) window comprising:
a first substrate and a second substrate oriented substantially parallel with one another;
a PV film disposed on at least one of the first and second substrates, wherein the PV film is transparent, and wherein the PV film is wavelength specific such that it selectively converts light energy at UV and/or IR wavelengths compared to visible wavelengths; and
an EC device disposed on at least one of the first and second substrates.

2. A photovoltaic-electrochromic (PV-EC) window comprising:
a first substrate and a second substrate oriented substantially parallel with one another;
a PV film disposed on at least one of the first and second substrates, wherein the PV film is transparent, and wherein the PV film comprises a perovskite-based material; and
an EC device disposed on at least one of the first and second substrates.

3. The PV-EC window of claim 2, wherein the perovskite-based material comprises an organotrihalometal.

4. The PV-EC window of claim 3, wherein the organotrihalometal is selected from the group consisting of (NH₃)MX₃, (CH₃NH₂)MX₃, (CH₃)₂N(H)MX₃,H(C═O)N(H)MX₃, HN═CN(H₂)MX₃, X—(CH₂)₃MX₃ and the like, where
M is Pb or Sn, and
each X is independently F, Cl, Br, or I.

5. The PV-EC window of claim 4, wherein M is Pb.

6. The PV-EC window of claim 4, wherein M is Sn.

7. The PV-EC window of claim 5, wherein at least one X is F.

8. The PV-EC window of claim 5, wherein at least one X is Cl.

9. The PV-EC window of claim 5, wherein at least one X is Br.

10. The PV-EC window of claim 5, wherein at least one X is I.

11. The PV-EC window of claim 3, wherein the organotrihalometal has the formula (R)₃N-M(X)₃, where
each R is independently selected from the group consisting of H and (C1-C6) alkyl, optionally substituted with one or more of the same or different R⁸ groups;
M is lead or tin;
each X is independently a halogen;
R⁸ is selected from the group consisting of Rₐ, R_{b}, Rₐ substituted with one or more of the same or different Rₐ or R_{b}, —ORₐ, —SRₐ, and —N(Rₐ)₂;
each Rₐ is independently selected from the group consisting of hydrogen, (C1-C6) alkyl, and (C1-C6) aryl; and either
(i) each R_{b} is independently selected from the group consisting of —NRₐRₐ, halogen, —CF₃, —CN, —C(O)Rₐ, —C(O)ORₐ and —C(O)NRₐRₐ; or
(ii) two of R_{b} combine to form ═O or ═N—Rₐ.

12. The PV-EC window of claim 6, wherein at least one X is F.

13. The PV-EC window of claim 6, wherein at least one X is Cl.

14. The PV-EC window of claim 6, wherein at least one X is Br.

15. The PV-EC window of claim 6, wherein at least one X is I.
